(19) United States
(12) Patent Application Publication
(10) Pub. No.: US 2024/0212991 A1
(43) Pub. Date: Jun. 27, 2024

(54) YTTRIUM ALUMINUM PEROVSKITE (YAP) BASED COATINGS FOR SEMICONDUCTOR PROCESSING CHAMBER COMPONENTS

(71) Applicant: Lam Research Corporation, Fremont, CA (US)

(72) Inventors: Eric A. PAPE, Santa Cruz, CA (US); David Joseph WETZEL, Santa Clara, CA (US); Lin XU, Fremont, CA (US); Satish SRINIVASAN, Newark, CA (US); Robin KOSHY, Fremont, CA (US); Douglas DETERT, Berkeley, CA (US); Jeremiah Michael DEDERICK, Livermore, CA (US)

(21) Appl. No.: 18/577,115

(22) PCT Filed: Aug. 2, 2022
(86) PCT No.: PCT/US2022/039133

§ 371 Date: Jan. 5, 2024

Related U.S. Application Data
(60) Provisional application No. 63/231,049, filed on Aug. 9, 2021.

(51) Int. Cl. H01J 37/32; B05D 1/02; H01L 21/683

(52) U.S. Cl. CPC H01J 37/32495; B05D 1/02; H01J 37/32119; H01J 37/32467; H01J 37/32715; B05D 2202/25; B05D 2203/30; H01J 2237/3341; H01L 21/6833

(57) ABSTRACT

A component for use in a semiconductor processing chamber is provided. A component body comprises a metallic material or ceramic material. A coating is disposed on a surface of the component body where the coating comprises a layer of yttrium aluminum oxide, the yttrium aluminum oxide layer being formed of a composition having a molar ratio of 1.0-0.9 yttrium to 1.0-1.1 aluminum over at least 90% of the yttrium aluminum oxide layer.

### CROSS-REFERENCE TO RELATED APPLICATION

This application claims the benefit of priority of U.S. Application No. 63/231,049, filed Aug. 9, 2021, which is incorporated herein by reference for all purposes.

### BACKGROUND

The present disclosure generally relates to the manufacturing of semiconductor devices. More specifically, the disclosure relates to chamber components used in manufacturing semiconductor devices.

During semiconductor wafer processing, plasma processing chambers are used to process semiconductor devices. Plasma processing chambers are subjected to plasmas halogen and/or oxygen, which may degrade components in the plasma processing chambers.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIG. 2A-FIG. 2D show an embodiment of a method for fabricating a component for use in a plasma processing chamber. FIG. 2A is a top view of a component substrate in the form of a pinnacle. FIG. 2B is a cross-sectional view of the component substrate of FIG. 2A. FIG. 2C is a cross-sectional detail view of a surface of the substrate of FIG. 2A. FIG. 2D is a cross-sectional detail view of an yttrium aluminum oxide layer coated to the substrate of FIG. 2A.

FIG. 3 is a schematic view of a plasma processing chamber that may be used in an embodiment.

### SUMMARY

To achieve the foregoing and in accordance with the purpose of the present disclosure, a component for use in a semiconductor processing chamber is provided. A component body comprises a metallic material or ceramic material. A coating is disposed on a surface of the component body, where the coating comprises a layer of yttrium aluminum oxide, the yttrium aluminum oxide layer being formed of a composition having a molar ratio of 1.0-0.9 yttrium to 1.0-1.1 aluminum over at least 90% of the yttrium aluminum oxide layer.

In another manifestation, a method for making a component for use in a semiconductor processing chamber is provided. A component body comprises a metallic material or ceramic material. A coating is deposited on a surface of the component body, where the coating comprises a layer of yttrium aluminum oxide, the yttrium aluminum oxide layer being formed of a composition having a molar ratio of 1.0-0.9 yttrium to 1.0-1.1 aluminum over at least 90% of the yttrium aluminum oxide layer.

These and other features of the present disclosure will be described in more detail below in the detailed description and in conjunction with the following figures.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

Various embodiments described herein provide semiconductor processing chamber components that are resistant to damage by arcing and/or erosion by processes such as plasma etching and thus inhibit or minimize consumption or degradation of the component that may occur from plasma and etching processes inherent in semiconductor processing systems such as a plasma processing chamber.

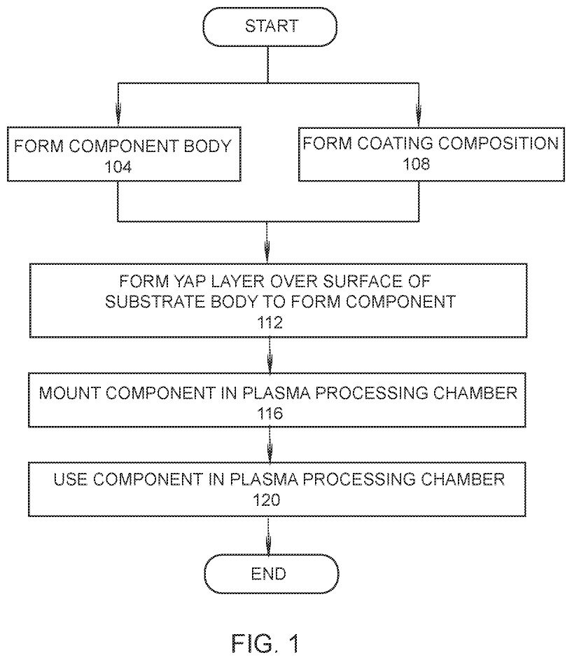

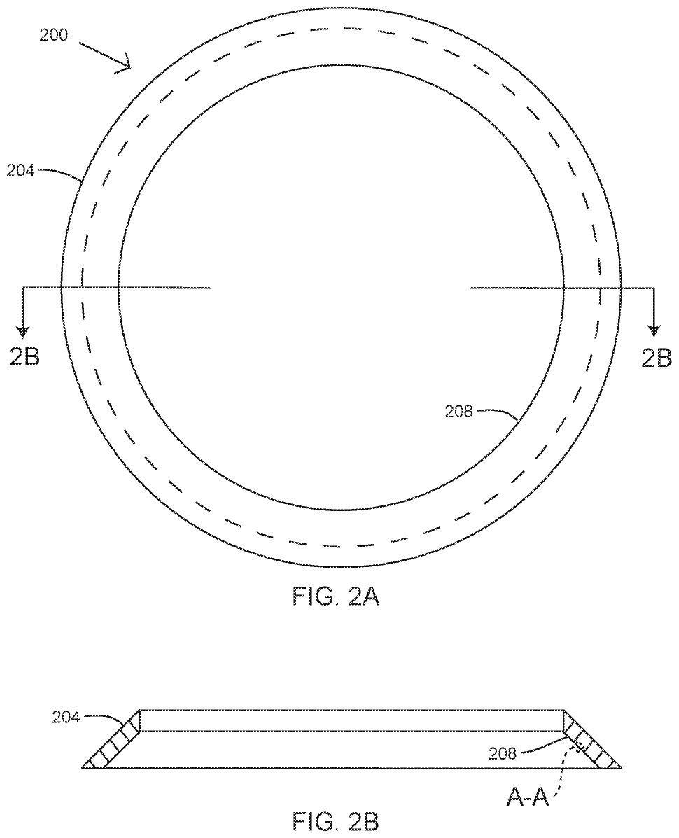

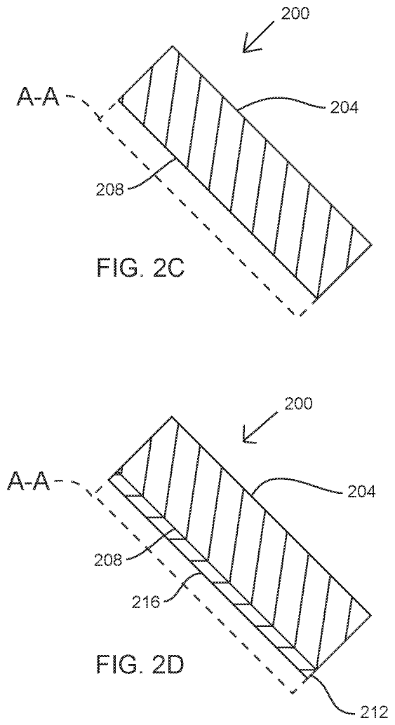

To facilitate understanding, FIG. 1 is a high level flow chart of a process of a first embodiment of fabricating and using a component for a semiconductor processing chamber such as a plasma processing chamber. A substrate body for a semiconductor processing chamber component is provided or formed (step 104). Referring to FIG. 2A through FIG. 2D, the provided substrate body 204 may be formed in the shape of a component 200 for use in a plasma processing chamber. Exemplary semiconductor processing chamber components include pinnacles, liners, liner doors, electrostatic chucks (ESCs), dielectric windows, chamber bodies, or like components.

In the embodiment shown in FIG. 2A through FIG. 2D, the component 200 is formed with a substrate body in the form of a pinnacle having at least one surface (e.g. inner surface 208) that is exposed to a semiconductor process within a semiconductor processing chamber. FIG. 2A is a top view of the component 200, and FIG. 2B is cross-sectional view of the component 200. FIG. 2C shows a close-up view of a section A-A at the inner surface 208 of substrate body 204.

In some embodiments, the substrate body 204 comprises a metallic material such as aluminum metal or aluminum alloy (e.g. Al6061-T6) or other metal alloy. In some embodiments, the substrate body 204 is anodized and/or sealed prior to any coating process. The anodization could be a type II or type III (hard) anodization. Sealing may be performed via any number of available sealing processes available in the art, including but not limited to, a hot deionized water (DI) sealing process.

The substrate body 204 may be formed via a number of various fabrication processes, e.g. by machining, or casting aluminum to form a specified component shape. In other embodiments, the substrate body 204 comprises a semiconductor or ceramic material such as like silicon, silicon carbide, alumina or yttria-stabilized zirconia. Sintered or multi-crystalline materials may also be used.

In an embodiment, the substrate body 204 may be formed by casting a semiconductor or ceramic material to form a specified component shape, e.g. by pouring or injecting a molten semiconductor or ceramic material into a mold, wherein the molten semiconductor or ceramic material cools in a hardened form in the mold to form a desired shape. In other embodiments, the semiconductor or ceramic material is solidified into a cylindrical shape, and then machined to the final geometry through abrasive grinding or other machining technique. It is also appreciated that the semiconductor or ceramic material can be formed via a variety of methods, such as casting or sintering, or made via various forms of additive manufacturing. These bulk material production methods may then be machined (or have material removed via a variety of other techniques such as laser ablation), if necessary, to the required target dimensions.

Prior to, after or contemporaneously with step 104, a coating composition comprising yttrium and aluminum is provided or formed (step 108). In one embodiment, the yttrium aluminum composition comprises a molar ratio of 1.0-0.9 yttrium to 1.0-1.1 aluminum. In another embodiment, the yttrium aluminum oxide composition comprises a powder composition of dispersed yttria and alumina in a molar ratio of 1.0-0.9 yttrium to 1.0-1.1 aluminum.

Referring to FIG. 1 and FIG. 2D, after the substrate body 204 and yttrium aluminum composition are provided, an yttrium aluminum oxide layer 212 (FIG. 2D) is deposited or otherwise formed over one or more surfaces 208 of the substrate body 204 (step 112) to form component 200. The yttrium aluminum oxide layer 212 provides a surface 216 that is particularly suited as a semiconductor process-facing surface that is resistant to sputter and corrosion, particularly from fluorine and other reactive species or aggressive etch processes or environments inherent in semiconductor and/or plasma processing chambers.

In one embodiment, the yttrium aluminum oxide layer 212 is formed by spray coating the yttrium aluminum composition over one or more surfaces 208 of the component body, resulting in an yttrium aluminum oxide layer 212 having a molar ratio of 1.0-0.9 yttrium to 1.0-1.1 aluminum. In some embodiments, the yttrium aluminum oxide layer 212 comprises a molar ratio of 1.0-2.7 to 1.0-3.3 yttrium to oxygen. In another embodiment, the yttrium aluminum oxide layer 212 comprises YAIO₃, also referred to as yttrium aluminum perovskite (YAP). In some embodiments, the composition of the yttrium aluminum oxide layer 212 is composed of at least 70% by weight yttrium aluminum perovskite (YAP), and in alternate embodiments at least 50% of the composition of the yttrium aluminum oxide layer 212 is amorphous with a stoichiometry as defined above. In other embodiments, at least 90% of the composition of the yttrium aluminum oxide layer 212 is amorphous with a stoichiometry as defined above. In further embodiments, at least 95% of material of the composition of the yttrium aluminum oxide layer 212 is amorphous with a stoichiometry as defined above.

In some embodiments, yttrium aluminum oxide layer 212 is applied via a thermal spray deposition technique such as HVOF (high-velocity oxygen fuel), SPS (suspension plasma spray), APS (atmospheric plasma spray), vacuum plasma spray, or like technique that provides a substantially uniform layer over the surface 208 of the substrate body 204.

Prior to deposition step 112, the one or more surfaces (e.g. inner surface 208) of the substrate body 204 may be pre-processed, e.g. texturing, roughening or other mechanical process to add surface roughness and/or minimize defects (e.g. cracks) in addition to a chemical processes such as etching, anodizing, or sealing, etc. to remove or substantially remove impurities or oxides (e.g. silicon oxide, aluminum oxide) and superficial damage to the substrate inner surface 208 or loosely attached microstructures on the substrate inner surface 208 that may have occurred during the fabrication process. For example, when priming a silicon substrate, a deionized (DI) water rinse may be performed on the substrate body 204, followed by a mixed acid etch to remove any superficial deficiencies, and also increase the surface roughness (i.e. controllably texture the surface with minimal mechanical or sub-surface damage) to improve adhesion of coating layers. In one embodiment, the substrate body 204 surface has a roughness between 2-7 μm RA roughness. In another embodiment, the substrate body 204 surface has a roughness between 4-6 μm RA roughness. Exemplary methods to texture/roughen the surface may include surface machining, grit or bead blasting, laser texturing, or the like processes.

In some embodiments, at least 5% by weight of the yttrium aluminum oxide layer 212 comprises a non-annealed crystalline structure. In other embodiments and least at least 15% of the yttrium aluminum oxide layer 212 comprises a non-annealed crystalline structure. A “non-annealed” is herein defined as a crystalline structure that is generated as a result of deposition step 112 without additional annealing to form or enhance the crystalline structure.

In various embodiments, the thickness of the yttrium aluminum oxide layer 212 may be varied upon one or more factors, including type of component, location of the component, geometry of the component, substrate material properties, cost, etc. According to one embodiment, the thickness of the yttrium aluminum oxide layer 212 is between about 50 micrometers (μm) to 600 μm. The yttrium aluminum oxide layer 212 of the present technology provides significant advancement over existing yttria coatings that are generally highly susceptible to corrosion and fluorine attack, also resulting in erosion and/or generation of reaction byproduct particulate in plasma reactors running modern halogen containing processes. The yttrium aluminum oxide layer 212 of the present technology also provides significant advancement over existing alumina coatings that have low sputter resistance due to lower molecular weight metal constituents and high levels of aluminum fluoride generation. Furthermore, while YAG (Y₃Al₅O₁₂) coatings appear to offer excellent fluorine and sputtering resistance, various mechanical and structural properties of such coating are not ideal when applied with thermal spray processes. In particular, local phase (glassy/amorphous vs. crystalline), chemistry, and microcracking from intrinsic stresses during APS deposition make such coatings non-ideal. The yttrium aluminum oxide layer 212 of the present technology also provides improved adhesion to the substrate body 204. In sum, the yttrium aluminum oxide layer 212 detailed herein, and in particular a yttrium aluminum oxide layer 212 having a molar ratio of 1.0-0.9 yttrium to 1.0-1.1 aluminum and composed of at least 70% by weight yttrium aluminum perovskite (YAP) over the thickness and surface of the layer, provides a higher crystalline content (above 5%), and thus improved mechanical and structural properties, along with improved sputter resistance, over coatings of yttria, alumina, or YAG. In addition, by having a close to a 1:1 molar ratio of aluminum to yttrium, the coating would be mainly YAP (more than 95% by weight) with some yttrium aluminum garnet (YAG), yttrium aluminum monoclinic (YAM), and yttrium oxide with almost no aluminum oxide (less than 0.1% by weight). Since yttrium aluminum oxide and yttria are more resistant to etching than aluminum oxide, providing a coating that has almost no aluminum oxide or is aluminum oxide free provides a more etch resistant coating.

After the component 200 is properly processed via steps 104 through 112 of FIG. 1, it is then mounted or otherwise installed in a semiconductor processing chamber, such as a plasma processing chamber (step 116, FIG. 1). The fabrication process illustrated in FIG. 1 is particularly useful for fabricating plasma processing chamber components using substrate materials that would normally be consumed or susceptible to corrosion from by the oxygen/halogen reactive species common in plasma processing chambers.

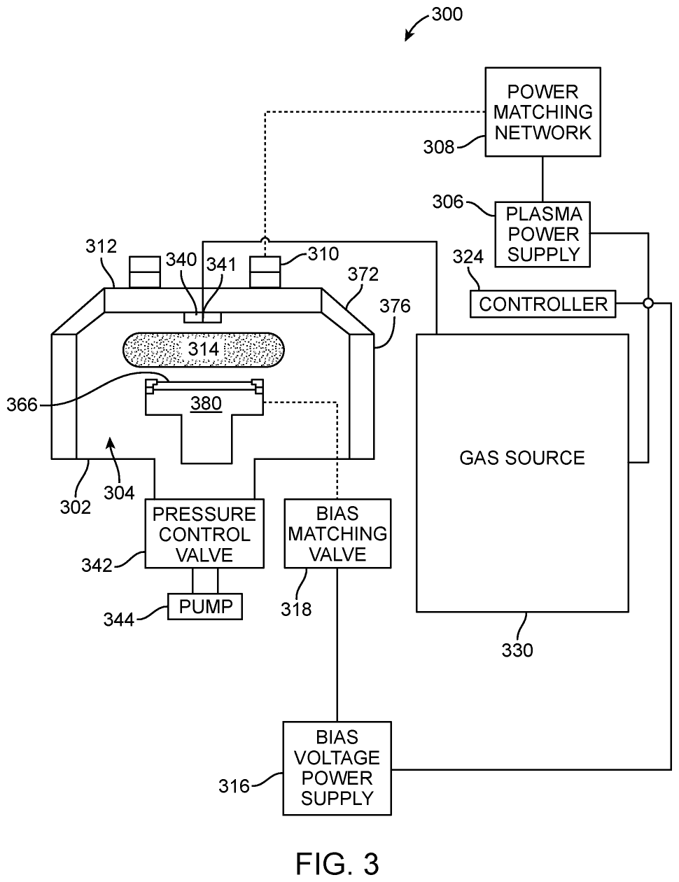

In some of the embodiments disclosed herein, the component 200 formed from the processes illustrated in FIG. 1, and FIG. 2A through FIG. 2D is directed to a particular application/installation as an pinnacle or similar component (e.g., pinnacle 372) for use in a plasma processing chamber (e.g. plasma processing chamber system 300 of FIG. 3). However, it is appreciated that the component 200 formed from the processes illustrated in FIG. 1, and FIG. 2A through FIG. 2D may be implemented as any number of components within plasma processing chamber system 300 or other semiconductor processing chambers, such as electrostatic chucks (ESC's), high-flow liners, dielectric windows, etc., among other having plasma or other semiconductor process-facing surfaces.

In one embodiment, the entire outer surface of the component 200 may be processed to include the yttrium aluminum oxide layer 212 as provided in the processes illustrated in FIG. 1, and FIG. 2A through FIG. 2D. However, it is appreciated that only a portion of the external surface of the component needs to be processed. For example, only a plasma-facing surface (e.g. inner surface 208—see FIG. 2B) may be process to have the yttrium aluminum oxide layer 212. Such a partial coating process may require masking portions that are not coated. In some embodiments, plasma-facing surface or semiconductor process-facing surface is a surface that is either exposed to plasma during plasma processing or is exposed to a reactive halogen species at high temperature and low pressure. The reactive halogen species may be formed from a remote plasma or thermally reactive fluorine.

Referring back to the process disclosed in FIG. 1, the component 200 is used in a plasma processing chamber (step 120) to facilitate semiconductor fabrication on the process wafer 366 (FIG. 3). The plasma processing may be one or more processes of etching, depositing, passivating, or another plasma process. The plasma processing may also be performed in combination with nonplasma processing.

To facilitate understanding, FIG. 3 schematically illustrates an example of a plasma processing chamber system 300 that may be used in an embodiment. The plasma processing chamber system 300 includes a plasma reactor 302 having a plasma processing chamber 304 therein. A plasma power supply 306, tuned by a power matching network 308, supplies power to a transformer coupled plasma (TCP) coil 310 located near a dielectric inductive power window 312 to create a plasma 314 in the plasma processing chamber 304 by providing an inductively coupled power.

A pinnacle 372 extends from a chamber wall 376 of the plasma processing chamber 304 to the dielectric inductive power window 312, forming a pinnacle ring. The pinnacle 372 is angled with respect to the chamber wall 376 and the dielectric inductive power window 312. For example, the interior angle between the pinnacle 372 and the chamber wall 376 and the interior angle between the pinnacle 372 and the dielectric inductive power window 312 may each be greater than 90° and less than 180º. The pinnacle 372 provides an angled ring near the top of the plasma processing chamber 304, as shown.

The TCP coil (upper power source) 310 may be configured to produce a uniform diffusion profile within the plasma processing chamber 304. For example, the TCP coil 310 may be configured to generate a toroidal power distribution in the plasma 314. The dielectric inductive power window 312 is provided to separate the TCP coil 310 from the plasma processing chamber 304 while allowing energy to pass from the TCP coil 310 to the plasma processing chamber 304. A wafer bias voltage power supply 316 tuned by a bias matching network 318 provides power to ESC assembly 380 to set the bias voltage when a process wafer 366 is placed on the ESC assembly 380. A controller 324 controls the plasma power supply 306 and the wafer bias voltage power supply 316.

A high flow liner or similar liner may be provided within the plasma processing chamber 304, and may also be formed, installed and used in accordance with the steps illustrated in FIG. 1. The high flow liner confines gas from the gas source 330 and may include a plurality of slots (not shown) maintain a controlled flow of gas to pass from the gas source 330 to the pump 344.

The plasma power supply 306 and the wafer bias voltage power supply 316 may be configured to operate at specific radio frequencies such as, for example, 13.56 megahertz (MHz), 27 MHz, 1 MHZ, 2 MHz, 60 MHz, 400 kilohertz (kHz), 2.54 gigahertz (GHz), or combinations thereof. Plasma power supply 306 and wafer bias voltage power supply 316 may be appropriately sized to supply a range of powers in order to achieve the desired process performance. For example, in one embodiment, the plasma power supply 306 may supply the power in a range of 50 to 5000 Watts, and the wafer bias voltage power supply 316 may supply a bias voltage in a range of 20 to 3000 volts (V). In addition, the TCP coil 310 and/or the ESC assembly 380 may be comprised of two or more sub-coils or sub-electrodes. The sub-coils or sub-electrodes may be powered by a single power supply or powered by multiple power supplies.

As shown in FIG. 3, the plasma processing chamber system 300 further includes a gas source/gas supply mechanism 330. The gas source 330 is in fluid connection with plasma processing chamber 304 through a gas inlet, such as a gas injector 340. The gas injector 340 has at least one borehole 341 to allow gas to pass through the gas injector 340 into the plasma processing chamber 304. The gas injector 340 may be located in any advantageous location in the plasma processing chamber 304 and may take any form for injecting gas. Preferably, however, the gas inlet may be configured to produce a “tunable” gas injection profile. The tunable gas injection profile allows independent adjustment of the respective flow of the gases to multiple zones in the plasma process chamber 304. More preferably, the gas injector is mounted to the dielectric inductive power window 312. The gas injector may be mounted on, mounted in, or form part of the power window. The process gases and by-products are removed from the plasma process chamber 304 via a pressure control valve 342 and a pump 344. The pressure control valve 342 and pump 344 also serve to maintain a particular pressure within the plasma processing chamber 304. The pressure control valve 342 can maintain a pressure of less than 1 Torr during processing. One or more edge rings may be placed around a top part of the ESC assembly 380. The gas source/gas supply mechanism 330 is controlled by the controller 324.

A process wafer 366 is placed in the plasma processing chamber 304, and in particular on or within the ESC assembly 380, as shown in FIG. 3. A plasma process is applied to the process wafer 366 (e.g. step 120 of FIG. 1). In this example, the plasma processing of the process wafer 366 is used to provide an etch of part of a stack on the process wafer 366, such as for etching a tungsten-containing layer in the stack. In this embodiment, the plasma process heats up to a temperature above 550° C. In addition, the plasma process deposits residue on the interior of the plasma processing chamber 304. After the plasma processing of the process wafer 366, the process wafer 366 is removed from the plasma processing chamber 304. The plasma processing chamber 304 is cleaned to remove deposited residue. In this embodiment, a reactive fluorine from a remote fluorine plasma is used to clean the interior of the plasma processing chamber 304. A pressure in the range of 1 milliTorr (mTorr) to 10 Torr is provided. The ESC assembly 380 has not sufficiently cooled and remains at a temperature above 500° C. After the cleaning is completed, a new process wafer 366 may be placed in the plasma processing chamber 304 to begin a new cycle. In another example, the plasma processing is used to provide an etch comprising a carbon layer, polysilicon layer, or oxide/nitride layer. In such example, wafer temperature is controlled in the range of 0° C. to 150° C. and the chamber is cleaned after wafer processing by in-situ oxygen (O₂) and nitrogen trifluoride (NF₃) plasma.

While the component 200 is shown in the embodiment of FIG. 3 with reference to use within an inductively coupled plasma (ICP) reactor for the plasma processing chamber system 300, it is appreciated that other components and/or types of plasma processing chambers may be used. A Kiyo or Sense.i plasma processing chamber manufactured by Lam Research Corp. of Fremont, CA may be used to practice an embodiment. Examples of other types of plasma processing chambers in which the component 200 may be used are capacitively coupled plasma processing chambers (CCP's), bevel plasma processing chambers, and the like processing chambers. In another example, the plasma processing chamber may be a dielectric processing chamber or conductor processing chamber.

In some embodiments, a coating has a thickness in the range of 30 nm to 2 μm. In some embodiments, the coating has a thickness in the range of 50 nm to 500 nm. In some embodiments, the coating has a thickness in the range of 50 nm to 250 nm. In some embodiments, a coating has a thickness in the range of 30 nm to 600 μm. Such a coating may be applied by at least one of or a combination of chemical vapor deposition (CVD) and atomic layer deposition (ALD). In some embodiments, a partial ALD and partial CVD process is used, where an ALD process is used where a perfect equilibrium is not achieved for each step in order to provide a quicker process.

In some embodiments, the component body and the coating are formed by co-sintering a component body ceramic powder and a coating ceramic powder together to form a ceramic laminate of different ceramic layers. In some embodiments, the coating formed by co-sintering has a thickness in the range of 100 μm to 1 cm. In some embodiments, the coating has a thickness in the range of 500 μm to 5 mm.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

What is claimed is:

1. A component for use in a semiconductor processing chamber, comprising:
a component body comprising a metallic material or ceramic material; and
a coating disposed on a surface of the component body;
wherein the coating comprises a layer of yttrium aluminum oxide, the yttrium aluminum oxide layer being formed of a composition having a molar ratio of 1.0-0.9 yttrium to 1.0-1.1 aluminum over at least 90% of the yttrium aluminum oxide layer.

2. The component, as recited in claim 1, wherein the component body comprises aluminum metal.

3. The component, as recited in claim 1, wherein the component body comprises silicon, silicon carbide, alumina, or yttria-stabilized zirconia.

4. The component, as recited in claim 1, wherein the yttrium aluminum oxide layer comprises at least 70% by weight yttrium aluminum perovskite (YAP).

5. The component, as recited in claim 1, wherein at least 5% by weight of the yttrium aluminum oxide layer comprises a non-annealed crystalline structure.

6. The component, as recited in claim 1, wherein the component comprises one or more of the following semiconductor processing chamber components: a pinnacle, a liner or an electrostatic chuck (ESC).

7. The component, as recited in claim 1, wherein the component comprises a dielectric window.

8. The component, as recited in claim 1, wherein the coating is formed on the surface via thermal spray coating of a powder composition comprising yttrium and aluminum.

9. The component, as recited in claim 8, wherein the powder composition comprises dispersed yttria and alumina in a molar ratio of 1.0-0.9 yttrium to 1.0-1.1 aluminum.

10. The component, as recited in claim 1, wherein the surface comprises a semiconductor process-facing surface and is resistant to sputter and corrosion.

11. A method for making a component for use in a semiconductor processing chamber, comprising:
forming a component body comprising a metallic material or ceramic material; and
depositing a coating on a surface of the component body;
wherein the coating comprises a layer of yttrium aluminum oxide, the yttrium aluminum oxide layer being formed of a composition having a molar ratio of 1.0-0.9 yttrium to 1.0-1.1 aluminum over at least 90% of the yttrium aluminum oxide layer.

12. The method, as recited in claim 11, wherein the component body comprises aluminum metal or metal alloy.

13. The method, as recited in claim 11, wherein the component body comprises silicon, silicon carbide, alumina, or yttria-stabilized zirconia.

14. The method, as recited in claim 11, wherein the yttrium aluminum oxide layer comprises at least 70% by weight yttrium aluminum perovskite (YAP).

15. The method, as recited in claim 11, wherein at least 5% by weight of the yttrium aluminum oxide layer comprises a non-annealed crystalline structure.

16. The method, as recited in claim 11, wherein the component comprises one or more of the following semiconductor processing chamber components: a pinnacle, a liner or an electrostatic chuck (ESC).

17. The method, as recited in claim 11, wherein the component comprises a dielectric window.

18. The method, as recited in claim 11, wherein the coating is formed on the surface via thermal spray coating of a powder composition comprising yttrium and aluminum.

19. The method, as recited in claim 18, wherein the powder composition comprises dispersed yttria and alumina in a molar ratio of 1.0-0.9 yttrium to 1.0-1.1 aluminum.

20. The method, as recited in claim 11, wherein the surface comprises a semiconductor process-facing surface and is resistant to sputter and corrosion.
